(19) United States
(12) Patent Application Publication
(10) Pub. No.: US 2024/0096714 A1
(43) Pub. Date: Mar. 21, 2024

(54) SEMICONDUCTOR CHIP AND METHOD FOR PRODUCING SEMICONDUCTOR PACKAGE INCLUDING THE SAME

(71) Applicant: Samsung Electronics Co., Ltd., Suwon-si (KR)

(72) Inventors: Kyungsoo LEE, Suwon-si (KR); Junho HUH, Suwon-si (KR)

(73) Assignee: Samsung Electronics Co., Ltd., Suwon-si (KR)

(21) Appl. No.: 18/462,067

(22) Filed: Sep. 6, 2023

(30) Foreign Application Priority Data
Sep. 19, 2022 (KR) 10-2022-0118150

(51) Int. Cl. H01L 21/66; H01L 21/56; H01L 23/528; H10B 20/25

(52) U.S. Cl. CPC H01L 22/22; H01L 21/56; H01L 23/528; H10B 20/25

(57) ABSTRACT

Provided are a semiconductor chip and a method of manufacturing a semiconductor package including the semiconductor chip. The semiconductor chip includes a front end of line (FEOL) including an active layer, a back end of line (BEOL) including a plurality of metal layers including a wire, an optional dicing line along which dicing is optionally performed, and an isolation block configured to process a signal for a discontinuous wire when the wire is discontinuous by being diced along the optional dicing line, and a chip die on which the active layer is not formed around a cross section cut by the optional dicing line. Thus, the production yield of the semiconductor chip may be improved, and the production costs thereof may be reduced.

### CROSS-REFERENCE TO RELATED APPLICATION

This application is based on and claims priority under 35 U.S.C. § 119 to Korean Patent Application No. 10-2022-0118150, filed on Sep. 19, 2022, in the Korean Intellectual Property Office, the disclosure of which is incorporated by reference herein in its entirety.

### BACKGROUND

The inventive concepts relate to semiconductor chips, and more particularly, to a semiconductor chip including an optional dicing line, and a method for producing a semiconductor package including the semiconductor chip.

Production costs of semiconductor chips are continuously increasing due to process miniaturization and/or an increase in wafer prices. Although the integration of transistors to improve the performance of semiconductor chips increases, the rate of process miniaturization decreases and the sizes of semiconductor chips relatively increase. The process yield of semiconductor chips decrease as the areas of the semiconductor chip increase, which may make it increasingly difficult to maintain or improve the process yield of semiconductor chips.

### SUMMARY

The inventive concepts provide a reduction in the production costs of semiconductor chips and an improvement in the yield of semiconductor chips.

Additional aspects will be set forth in part in the description which follows and, in part, will be apparent from the description, or may be learned by practice of the presented example embodiments.

According to an aspect of the inventive concepts, there is provided a semiconductor chip including a front end of line (FEOL) including an active layer, a back end of line (BEOL) including a plurality of metal layers including a wire, an optional dicing line along which dicing is optionally performed, and an isolation block configured to process a signal for a discontinuous wire when the wire is discontinuous by being diced along the optional dicing line, wherein the semiconductor chip is composed of chip dies on which the active layer is not formed around a cross-section obtained by cutting along the optional dicing line.

According to another aspect of the inventive concepts, there is provided a semiconductor chip including an active layer, a semiconductor wiring layer including a wire, an optional dicing line along which dicing is optionally performed; and an isolation block configured to process a signal for a discontinuous wire when the wire is discontinuous by being diced along the optional dicing line, wherein the semiconductor chip is composed of chip dies on which the active layer is not formed around a cross-section of the optional dicing line.

According to another aspect of the inventive concepts, there is provided a method of producing a semiconductor package, the method including identifying first known good dies (KGDs) by testing dies including an optional dicing line along which dicing is optionally performed, selecting at least some of the tested dies for dicing, producing separated dies by dicing the selected dies along the optional dicing line, identifying second KGDs by testing the separated dies, and packaging each of at least some of the first KGDs or the second KGDs.

### BRIEF DESCRIPTION OF THE DRAWINGS

Example embodiments will be more clearly understood from the following detailed description taken in conjunction with the accompanying drawings in which:

FIG. 1 is a view illustrating a semiconductor chip according to example embodiments;

FIG. 2 is a view illustrating a semiconductor chip according to example embodiments;

FIG. 3 is a cross-sectional view of a semiconductor chip according to example embodiments;

FIG. 4 is a side view illustrating that a die is diced along an optional dicing line and dies obtained by the dicing are individually packaged, according to example embodiments;

FIG. 5 is a side view illustrating that a die is packaged without being diced along an optional dicing line, according to example embodiments;

FIG. 6 is a conceptual diagram illustrating types of dies that may be produced when there is one optional dicing line on a chip die, according to example embodiments;

FIG. 7 is a conceptual diagram illustrating a case in which a plurality of dies on a wafer identified as KGDs or KBDs through a test are diced by an optional dicing line, according to example embodiments;

FIG. 8 is a conceptual diagram illustrating a case in which a KBD is selected from a plurality of dies on a wafer identified as KGDs or KBDs through a test and the KBDs are diced by an optional dicing line, according to example embodiments;

FIG. 9 is a conceptual view illustrating a case in which two optional dicing lines are formed on a die, according to example embodiments; and

FIG. 10 is a flowchart of a method of manufacturing a semiconductor package including a semiconductor chip, according to example embodiments.

### DETAILED DESCRIPTION OF EXAMPLE EMBODIMENTS

Hereinafter, example embodiments of the inventive concepts will be described more fully with reference to the accompanying drawings. In the accompanying drawings, like reference numerals may refer to like elements, and repeated descriptions of the like elements will be omitted.

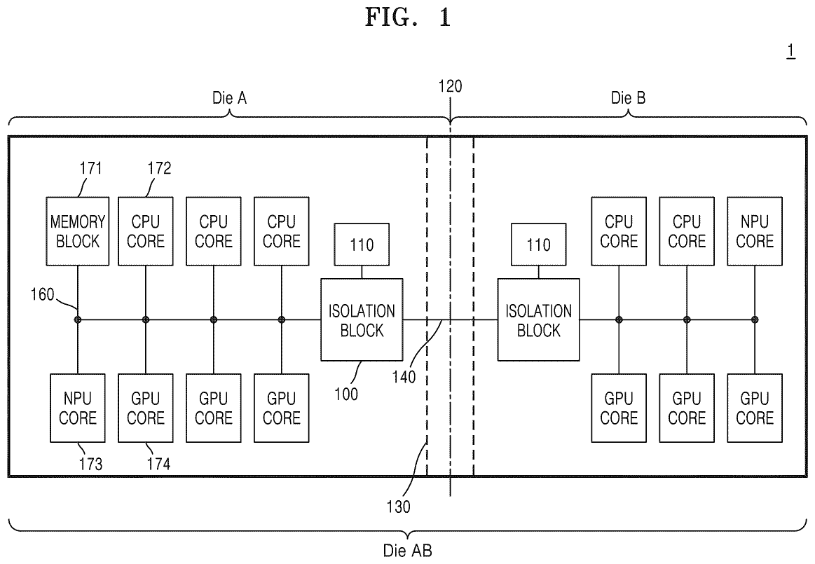

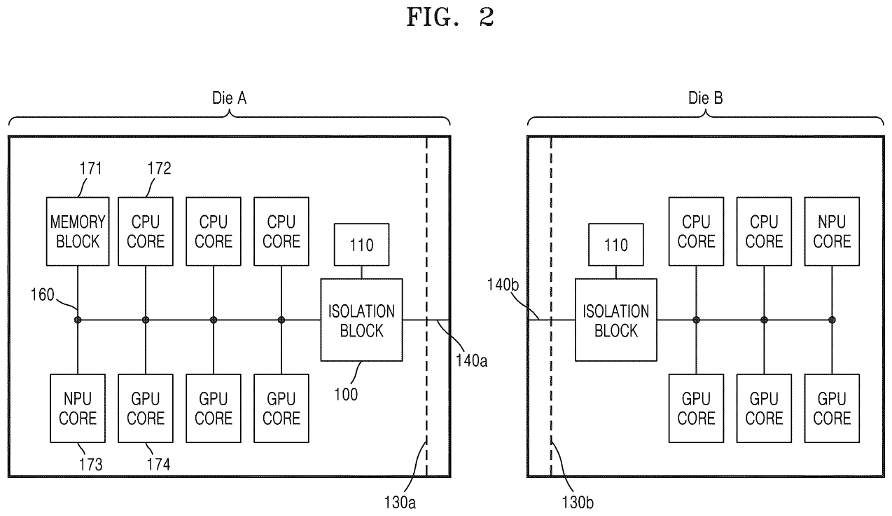

FIG. 1 is a view illustrating a semiconductor chip according to example embodiments. FIG. 2 is a view illustrating a semiconductor chip according to example embodiments.

Referring to FIGS. 1 and 2, the semiconductor chip may include a chip die 1, and the chip die 1 may have a rectangular shape. Various types of cores and blocks may be provided on the chip die 1. The various types of cores may include central processing unit (CPU) cores, graphics processing unit (GPU) cores, and neural processing unit (NPU) cores. A block may include a memory block.

Within one chip die 1, the various types of cores may be configured to be connected together through a bus 160, which is a path through which data is transmitted as an electrical signal. Alternatively, the various types of cores may receive power through the bus 160.

A memory block 171 may be implemented as volatile memory. The volatile memory may include at least one of dynamic random access memory (DRAM), synchronous DRAM (SDRAM), double data rate (DDR) SDRAM, low power double data rate (LPDDR) SDRAM, graphics double data rate (GDDR) SDRAM, rambus DRAM (RDRAM), and static RAM (SRAM), but example embodiments of the inventive concepts are not limited thereto. An optional dicing line 120 (a line where dicing may occur) may be provided on the chip die 1. The chip die 1 may be diced along the optional dicing line 120. The optional dicing line 120 may be positioned to be diced in a short length direction of the chip die 1 capable of having a rectangular shape. The dicing may be laser dicing, but example embodiments of the inventive concepts are not limited thereto.

When the chip die 1 is diced along one optional dicing line 120, the chip die 1 may be divided into two chips. The two chips (die A and die B) may include different semiconductor devices. Even when the two chips are separated from each other, each of the chips may be configured to have a unique function. According to example embodiments, the chip die 1 may include one memory block 171, five CPU cores 172, two NPU cores 173, and six GPU cores 174. On the basis of the optional dicing line 120, the die A may include one memory block 171, three CPU cores 172, one NPU core 173, and three GPU cores 174. On the basis of the optional dicing line 120, the die B may include three CPU cores 172, one NPU core 173, and three GPU cores 174. Accordingly, when the chip die 1 is diced and divided into the die A and the die B, semiconductor chips having different performances may be produced. When dicing is not performed along the optional dicing line 120, a die AB may include one memory block 171, five CPU cores 172, two NPU cores 173, and six GPU cores 174. Therefore, when dicing is not performed on the optional dicing line 120, a chip having the largest number of cores or blocks may be produced. When dicing is performed along the optional dicing line 120, dies may be obtained, and the performance of each of the dies may be different from that of a die not subjected to dicing.

The chip die 1 is configured to operate as a single chip even when dicing is not performed along the optional dicing line 120. In order for the chip die 1 to operate as a single chip, the die A and the die B may be electrically connected to each other through an inter-die connection wire 140. The inter-die connection wire 140 may extend across the optional dicing line 120. Accordingly, when a general chip die is diced along the optional dicing line 120, the inter-die connection wire 140 may be discontinued due to the dicing. When an electrically connected wire is discontinued due to dicing, a dicing cross-section may be damaged due to dicing. Due to disconnection, electrical signals transmitted and received between a plurality of electrically-connected semiconductor devices may be floated or shorted. When electrical signals flowing through a wire are floated or shorted, each die may not function properly, an error may occur during operation, internal wiring and cores may be damaged, or the die may become inoperable.

Therefore, in order to address this problem, the chip die 1 according to example embodiments may include an isolation block 100 to reduce or prevent defects, damage, malfunction, etc. of a chip divided by dicing.

For example, the isolation block 100 is configured to reduce or prevent the aforementioned problems from being caused by electrical signals flowing through the inter-die connection wire 140. The isolation block 100 may be set as an inactive state when the chip die 1 is not diced along the optional dicing line 120. In other words, the isolation block 100 may have an inactive state by default. When the chip die 1 is diced along the optional dicing line 120, the isolation block 100 may be set as an active state. The setting of the isolation block 100 to be active may be due to an external signal or due to a structure embedded in the chip die 1. According to example embodiments, the chip die 1 may include a One Time Programmable (OTP) memory 110. The isolation block 100 may be configured to be activated due to the OTP memory 110. The isolation block 100 may be an electric circuit included in the chip die 1.

An OTP memory is a general term for a memory that cannot be written any more and only allows reading after one program operation. The number of read operations on the OTP memory is not limited. Electrically Erasable Programmable Read Only Memory (EEPROM) that stores binary information in a floating gate memory cell, flash memory from which a program function has been deleted, and Electrically Programmable ROM (EPROM) from which an external window has been removed may be used as the OTP memory. The OTP memory may be of a fuse type. The fuse type is a type that is the most commonly used as an OTP memory.

The fuse type refers to a type of determining binary information according to whether a fuse has been blown. When a non-volatile memory is embedded in a power management integrated circuit (PMIC), a separate production process may be added when an EEPROM or a flash memory is embedded. An electrical fuse type or an anti-fuse type does not require an additional process, and thus an OTP memory of the electrical fuse type or anti-fuse type is widely used.

The anti-fuse type is a type of performing fusing by shorting an oxide layer by applying a voltage greater than or equal to a breakdown voltage to a transistor gate oxide layer. An electrical fuse type memory may include an electrical fuse, a read transistor, and a programming transistor. When a specific voltage is applied to the electrical fuse through a selection line and the programming transistor is turned on, a rapid current may flow in both ends of a fuse. A sense amplifier may read a voltage generated by allowing a current path to be destroyed due to the rapid current. Accordingly, the electrical fuse type memory may operate as the OTP memory.

A die may be diced along the optional dicing line 120, and thus the inter-die connection wire 140 may be discontinuous. When power is connected to the dies (die A and die B) obtained by dicing due to the disconnection, the OTP memory 110 may be configured to operate through electrical signals respectively generated by first and second inter-die connection wires 140a and 140b. Alternatively, a separate circuit may be configured so that an OTP memory operates due to the discontinuous inter-die connection wires 140a and 140b. Operating the OTP memory is not limited thereto.

When the OTP memory 110 operates, the isolation block 100 may be activated. Accordingly, the isolation block 100 may reduce or prevent damage or malfunction from occurring due to the discontinuous inter-die connecting wires 140a and 140b when the dies (die A and die B) operate. Alternatively, the isolation block 100 may be activated by an electrical signal received from an external pin or external memory that may be connected to the outside. The external pin and the external memory are known to one of ordinary skill in the art, and thus a detailed description thereof will be omitted.

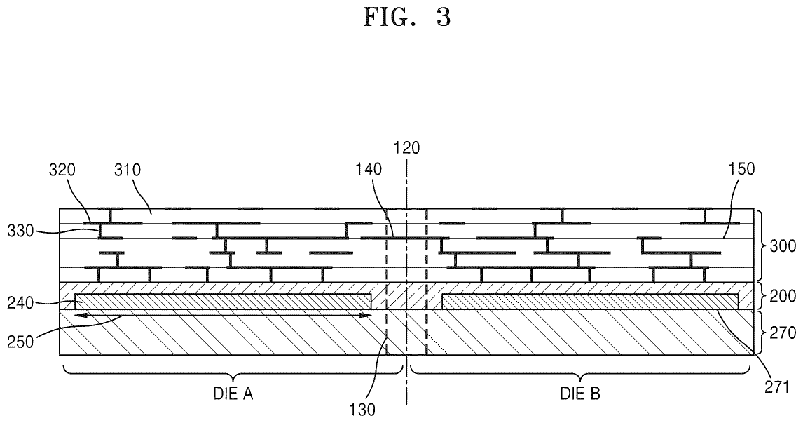

FIG. 3 is a cross-sectional view of a semiconductor chip according to example embodiments. Referring to FIG. 3, the semiconductor chip may include a semiconductor substrate 270. The semiconductor substrate 270 may constitute a substrate level layer. The semiconductor substrate 270 may be formed as a semiconductor wafer. The semiconductor substrate 270 may include a group IV material or a group III-V compound. The semiconductor substrate 270 may be formed as a single crystal wafer, for example, a silicon single crystal wafer.

However, the semiconductor substrate 270 is not limited to the single crystal wafer, and may be any of various wafers such as an epi or epitaxial wafer, a polished wafer, an annealed wafer, and a silicon on insulator (SOI) wafer. The epitaxial wafer denotes a wafer obtained by growing a crystal material on a single crystal silicon substrate. The semiconductor substrate 270 may be a silicon substrate.

The integrated circuit layer 240, an interlayer insulating layer (not shown), and a contact plug layer (not shown) formed on the semiconductor substrate 270 may constitute an FEOL 200. The FEOL 200 may be referred to as a front end of line in terms of production process.

The semiconductor chip may include the integrated circuit layer 240. The integrated circuit layer 240 may include circuit devices, such as transistors, capacitors, and/or resistors. According to a structure of the integrated circuit layer 240, the semiconductor chip may function as a memory device or a logic device. For examples, the memory device may include a DRAM, an SRAM, a flash memory, an EEPROM, a PRAM, an MRAM, and an RRAM. For examples, the logic device may include a central processing unit (CPU), a graphics processing unit (GPU), a neural processing unit (NPU), an image signal processor (ISP), and a digital signal processor (DSP). Since the structure of an integrated circuit layer is commonly known, this does not limit the scope of the inventive concepts.

A region of the semiconductor substrate 270 below the integrated circuit layer 240 may be the active layer 250, and a portion of a lower portion of a first surface 271 of the semiconductor substrate 270 in which the integrated circuit layer 240 is not formed may be a non-active layer. Impurity-doped regions formed under the first surface 271 of the semiconductor substrate 270, for example, source and drain regions, a well region, and an isolation region are not separately shown.

An interlayer insulating layer (not shown) may be interposed on the semiconductor substrate 270 and the integrated circuit layer 240. The interlayer insulating layer may be formed as a silicon oxide layer. A contact plug layer electrically connected to the integrated circuit layer 240 is formed in the interlayer insulating layer. The contact plug layer may be formed as a metal layer, for example, a tungsten layer.

Wiring insulating layers 310, metal wiring layers 320, and wiring via layers 330 formed on the FEOL may constitute a BEOL 300. The BEOL 300 may be referred to as a back end of line in terms of production process.

The semiconductor chip may include the metal wiring layers 320. The metal wiring layers 320 may be formed as metal layers, for example, copper layers, aluminum layers, or tungsten layers. The metal wiring layers 320 electrically connected to semiconductor substrate 270 and the integrated circuit layer 240 may be formed sequentially over the semiconductor substrate 270 and the integrated circuit layer 240. The metal wiring layers 320 may include a plurality of metal wiring layers. An uppermost metal wiring layer among the metal wiring layers 320 may be a metal wiring layer positioned far from the integrated circuit layer 240 among the metal wiring layers 320. The total number of wiring layers constituting the plurality of metal wiring layers may vary depending on manufacturing processes.

The semiconductor chip may include the wiring insulating layers 310. The wiring insulating layers 310 may insulate the plurality of metal wiring layers 320 from one another. The wiring insulating layers 310 may be formed as silicon oxide layers. The wiring insulating layers 310 may include a plurality of wiring insulating layers.

The semiconductor chip may include the wiring via layers 330. The wiring via layers 330 may electrically connect the metal wiring layers 320 to one another within the wiring insulating layers 310. The wiring via layers 330 may be formed as metal layers, for example, copper layers, aluminum layers, or tungsten layers. The wiring via layers 330 may include a plurality of wiring via layers.

Any one of the plurality of metal wiring layers, which is a signal layer 150, may include the inter-die connection wire 140. The inter-die connection wire 140 may be a wire that passes through the optional dicing line 120. As described above, the die A and the die B may be electrically connected to each other through the inter-die connection wire 140.

A region in which the integrated circuit layer 240 or the active layer 250 is not formed around the selective dicing line 120 is referred to as a first region 130 The first region 130 may include the semiconductor substrate 270, the FEOL 200, and the BEOL 300. The FEOL 200 included in the first region 130 does not include the integrated circuit layer 240 or the active layer 250.

An integrated circuit layer 240 of FIG. 3 or an active layer 250 of FIG. 3 may not be formed around the optional dicing line 120 corresponding to a portion of the die. Along the optional dicing line 120, the semiconductor chip may be diced into the die A and the die B. As described above, the isolation block 100 may be included in the semiconductor chip in order to reduce or prevent a problem from occurring due to disconnection such as floating or shorting of an electrical signal that is to flow through the inter-die connection wire 140. When the inter-die connection wire 140 is discontinuous due to dicing and the number of metal wiring layers 320 on which the inter-die connection wire 140 is formed is large, the possibility that problems occur due to the disconnection may increase. In other words, damage to a diced cross-section may occur due to disconnection caused by dicing, and thus the possibility that problems occur due to the disconnection may increase.

Therefore, it may be advantageous for a stable operation of a divided die when the number of metal wiring layers formed in the first region 130 is less than the number of metal wiring layers formed in areas other than the first region 130. As described above, typically, the total number of wiring layers constituting the plurality of metal wiring layers may vary depending on manufacturing processes. For example, the total number of metal wiring layers may be 20. The number of metal wiring layers in which the inter-die connection wires 140 are formed in the first region 130 may be equal to or less than the number of metal wiring layers included in the BEOL 300 other than the first region 130. In order to reduce or minimize occurrence of a problem due to the disconnection and at the same time to ensure a stable operation of each die obtained by dicing, the inter-die connection wire 140 may be formed on one metal wiring layer.

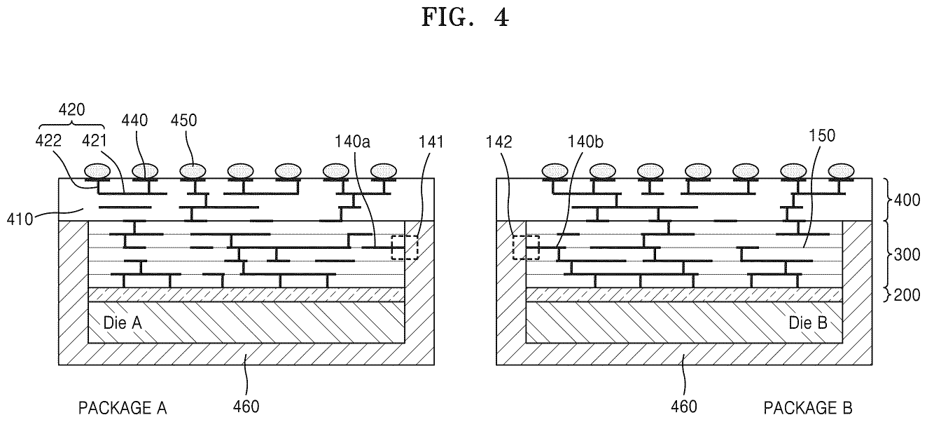

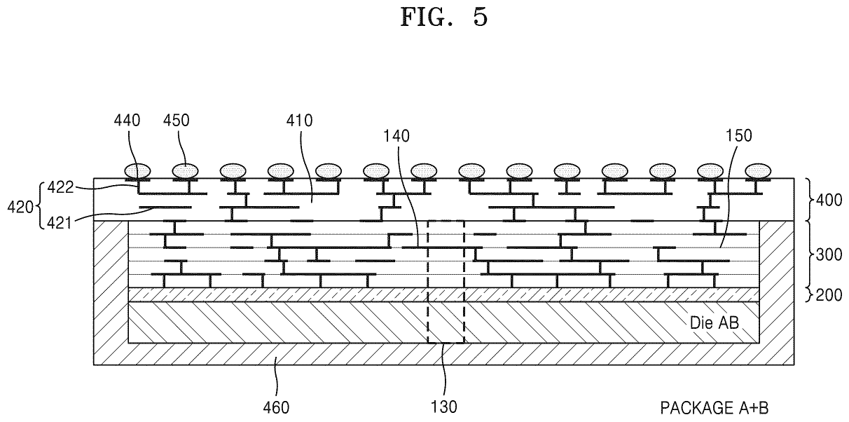

FIG. 4 is a side view illustrating that a die is diced along an optional dicing line and dies obtained by the dicing are individually packaged, according to example embodiments. FIG. 5 is a side view illustrating that a die is packaged without being diced along an optional dicing line, according to example embodiments.

Referring to FIGS. 4 and 5, the semiconductor chip of FIG. 3 may or may not be diced along the optional dicing line 120. When the semiconductor chip of FIG. 3 is diced, the dies A and dies B obtained by the dicing may be produced. When the semiconductor chip of FIG. 3 is not diced, the die AB may be produced without changes. The example embodiments of FIG. 4 show packaging of a die divided into the dies A and dies B. The example embodiments of FIG. 5 show that the die AB has been packaged.

Referring to FIG. 4, a semiconductor package may include a redistribution structure 400, the semiconductor chip (die A and die B), and a molding member 460. A horizontal width and a horizontal area of the redistribution structure 400 may have greater values than a horizontal width and a horizontal area of the semiconductor chip (die A and die B).

The redistribution structure 400 may include a redistribution pattern 420 and a plurality of redistribution insulating layers 410 covering the redistribution pattern 420. The plurality of redistribution insulating layers 410 may be mutually stacked in a vertical direction. The plurality of redistribution insulating layers 410 may be formed from material films made of organic compounds. For example, each of the plurality of redistribution insulating layers 410 may be formed from a photo imageable dielectric (PID), an Ajinomoto Build-up Film (ABF), or photosensitive polyimide (PSPI).

The redistribution pattern 420 may include a plurality of redistribution line patterns 421 disposed between the plurality of redistribution insulating layers 410, and a plurality of redistribution via patterns 422 extending by penetrating at least one of the plurality of redistribution insulating layers 410. The plurality of redistribution via patterns 422 may electrically connect the plurality of redistribution line patterns 421 positioned on different layers to one another in a vertical direction. For example, the redistribution pattern 420 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof, but example embodiments are not limited thereto.

Some of the plurality of redistribution line patterns 421 are provided on a lower surface of the redistribution structure 400 to constitute bump pads connected to chip connection bumps (not shown) attached to the semiconductor chip (die A and die B) and connection pads connected to a conductive post (not shown). In addition, some of the plurality of redistribution line patterns 421 may be provided on an upper surface of the redistribution structure 400 to constitute form external connection pads 440 connected to external connection terminals 450. The external connection terminals 450 may be, for example, solder balls or solder bumps.

At least some of the plurality of redistribution line patterns 421 may be formed together with some of the plurality of redistribution via patterns 422 to be integrated with the some of the plurality of redistribution via patterns 422. For example, some of the plurality of redistribution line patterns 421 may be formed together with redistribution via patterns 422 in contact with lower surfaces of the some of the plurality of redistribution line patterns 421 to be incorporated with the redistribution via patterns 422.

Although the redistribution structure 400 is illustrated as being a redistribution board formed using a redistribution process, a printed circuit board (PCB) may be used as the redistribution structure 400. The redistribution structure 400 may be disposed on an upper surface of the semiconductor chip (die A and die B). For example, the semiconductor chip (die A and die B) may be electrically connected to the redistribution structure 400 through chip connection bumps (not shown), such as micro bumps, in a flip chip manner.

A molding member 460 may be disposed on one surface of the redistribution structure 400 to cover at least a portion of the semiconductor chip (die A and die B). For example, the molding member 460 may extend along sidewalls of the semiconductor chip (die A and die B). In other words, the molding member 460 may extend along sidewalls of the BEOL 300, sidewalls of the FEOL 200, and sidewalls of the semiconductor substrate 270. According to example embodiments, the molding member 460 may include an insulating polymer or epoxy resin. For example, the molding member 460 may include an epoxy mold compound (EMC).

The inter-die connection wire 140 are cut along the optional dicing line 120 and divided into a first inter-die connection wire 140a on the die A and a second inter-die connection wire 140b on the die B. A cross-section 141 of the first inter-die connection wire 140a may be exposed on a lateral surface of a metal wire layer of the die A. A cross-section 142 of the second inter-die connection wire 140b may be exposed on a lateral surface of a metal wire layer of the die B. The exposed cross-sections 141 and 142 of the first and second inter-die connection wires 140a and 140b may directly contact the molding member 460. In other words, the BEOL 300 including the exposed cross-sections 141 and 142 of the first and second inter-die connection wires 140a and 140b may be surrounded by the molding member 460.

Referring to FIG. 5, as described above, when a die is not diced, the die AB may be packaged. A description of FIG. 5 that is the same as that given above with reference to FIG. 4 will not be repeated herebelow. The inter-die connection wire 140 formed in the first region 130 may be formed on only one metal wiring layer. A molding member 460 may be disposed on one surface of the redistribution structure 400 to cover at least a portion of the semiconductor chip (die A and die B). For example, the molding member 460 may extend along the sidewalls of the semiconductor chip (die AB). In other words, the molding member 460 may extend along the sidewalls of the BEOL 300, the sidewalls of the FEOL 200, and the sidewalls of the semiconductor substrate 270. A description of the molding member 460 that is the same as given above with reference to FIG. 4 will not be repeated herebelow.

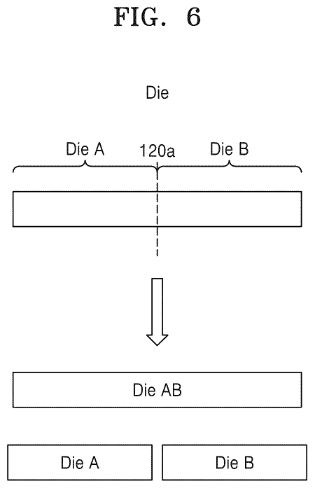

FIG. 6 is a conceptual diagram illustrating types of dies that may be produced when there is one optional dicing line on a chip die, according to example embodiments.

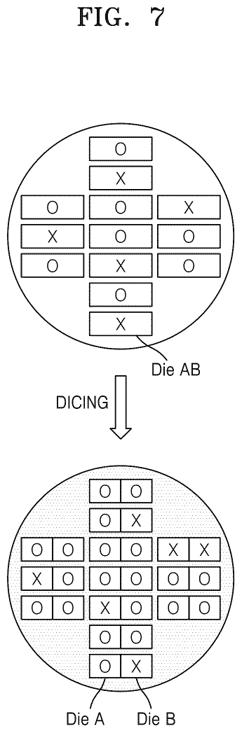

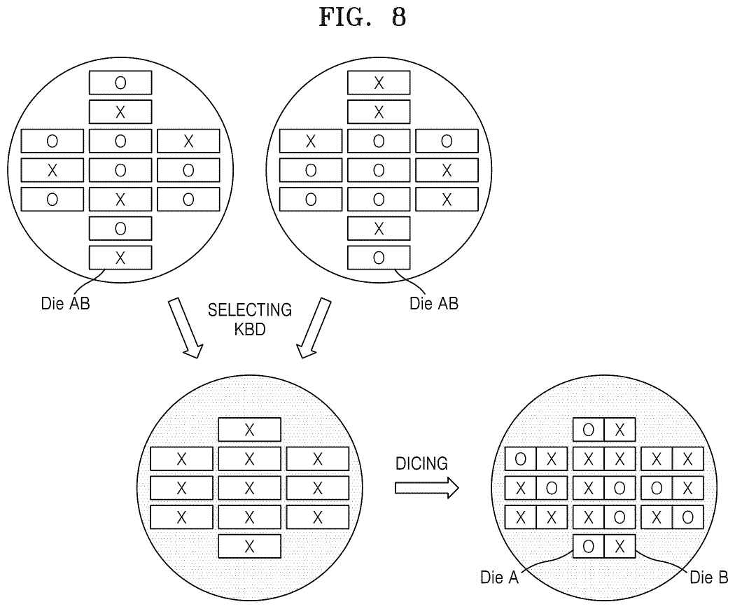

Referring to FIG. 6, the chip die may include one optional dicing line 120. Together with the one optional dicing line 120, the chip die may include the above-described first region 130 and the above-described inter-die connection wire 140. According to example embodiments, when a die AB is diced along the one optional dicing line 120, die A and die B may be formed. Alternatively, a die AB capable of functioning as a single chip without dicing may be used without changes. Therefore, when a die includes one optional dicing line 120, the die AB, the die A, and the die B, which are products capable of functioning as independent dies, respectively, may be produced. The die AB, which is a die not yet been divided by dicing, may become a Known Good Die (KGD) or Known Bad Die (KBD), which will be described later. A description of example embodiments in which the die AB is divided by dicing to become a KGD or KBD will be given with reference to FIGS. 7 and 8.

FIG. 7 is a conceptual diagram illustrating a case in which a plurality of dies on a wafer identified as KGDs or KBDs through a test are diced by an optional dicing line, according to example embodiments.

Referring to FIG. 7, a test may be performed on dies formed on a wafer. The test may include an electrical die sorting (EDS) process. The EDS process may include an electrical (ET) test, a wafer burn in (WBI) process, a hot/cold test, a repair and final test, and an Inking process.

The ET test includes a process of determining whether a semiconductor integrated circuit operates, by testing parameters of an electric direct current (DC) voltage and current characteristics for individual devices (transistors, resistors, capacitors, and diodes) necessary for the operation of the semiconductor integrated circuit. The WBI process includes a process of applying heat of a certain temperature to a wafer and then applying an alternating current (AC) or DC voltage to identify potential defect factors such as product bonding and weak parts. The hot/cold test includes identifying whether there is a defect among each chips on a wafer through an electrical signal in an environment higher or lower than a room temperature in order to determine whether chips operate normally at a specific temperature. Chips determined to be repairable in the hot/cold test may be repaired, and, after the repair is completed, a normal or a defect may be finally determined by verifying again the repaired chips through the final test. The inking process refers to a process of enabling a defect to be identified with the naked eye by applying a special ink to a defective chip. The hot/cold test includes a process of distinguishing between a chip determined to be defective, a chip processed as a defect as a result of re-verification in the final test, and an unfinished semiconductor chip from one another. In the past inking process, ink is directly applied to defective chips. However, in recent years, a normality/defect may be determined as data. Hereinafter, the test may refer to an EDS process. A test process may include at least a portion of the above-described test or process, and the test is not limited to the foregoing description.

A plurality of dies on the wafer may undergo testing. Some of the plurality of dies that have undergone the test may be determined to be KGDs, and the others may be determined to be KBDs. According to example embodiments, a KGD determined through testing before being diced may be referred to as a first KGD. Likewise, a KBD determined through the test before being diced may be referred to as a first KBD. In the drawings, the first KGD may be indicated by “O” and the first KBD may be indicated by “X”. As shown in FIG. 7, the die AB before being diced may be identified as and classified into a first KGD or a first KBD through the above test.

If necessary, the die AB, which is the first KGD, may be diced along an optional dicing line. The plurality of dies on which the test has been made may be moved and positioned on a carrier wafer. After the plurality of dies are diced on the carrier wafer, the test may be performed on divided dies. A KGD according to a second test after dicing may be referred to as a second KGD. Likewise, a KBD according to a second test after dicing may be referred to as a second KBD. A die AB, which is the first KGD, may be manufactured as a semiconductor chip without being diced, or the die AB may be manufactured as semiconductor chips after being diced along an optional dicing line. Dicing of the first KGD along the optional dicing line may vary depending on product demand or production plans. When the first KGD is diced, two second KGDs, namely, die A and die B, are formed. When the first KBD is diced, two dies A and B are formed. The two dies formed when the first KBD is diced may be each identified as and classified into either a KGD or a KBD. For example, both the die A and the die B may be KBDs, the die A and the die B may be a second KGD and a second KBD, respectively, or the die A and the die B may be a second KBD and a second KGD, respectively. A plurality of chips may be manufactured by dicing dies corresponding to the first KBD, rather than processing, as defects, the dies corresponding to the first KBD among dies AB produced in a single process. As in the case where the die A is a second KGD or the die B is a second KGD, it is possible to utilize some KGDs by dicing a not-yet-diced die instead of processing the not-yet-diced die as a defect. For example, referring to FIG. 7, because 8 out of a total of 13 dies tested before being diced are KGDs, good dies (GD) of about 61.5% may be obtained. Because 20 out of a total of 26 dies tested after being diced are KGDs, GDs of about 76.9% may be obtained. Therefore, dies may be produced through optional dicing according to respective needs of dies AB, dies A, and dies B, and a second KGD may be produced by dicing a die that is a first KBD, leading to an improvement in the production yield and/or a reduction in the production costs.

FIG. 8 is a conceptual diagram illustrating a case in which a KBD is selected from a plurality of dies on a wafer identified as KGDs or KBDs through a test and the KBDs are diced by an optional dicing line, according to example embodiments. A description of FIG. 8 that is the same as that given above with reference to FIG. 7 will not be repeated herebelow. Referring to FIG. 8, only the first KBDs except for the first KGDs may be selected and collected to be diced along an optional dicing line. At this time, the first KBDs may be positioned to be arranged on a carrier wafer, and may be diced along the optional dicing line. When dies corresponding to a result of the dicing are tested after dicing, some of the dies may be second KGDs and the others may be second KBDs. Prior to the dicing, the plurality of dies are all first KBDs. However, a portion of the die A or the die B may become a second KGD through dicing, leading to a reduction in the production costs and an improvement in the yield of semiconductor chips.

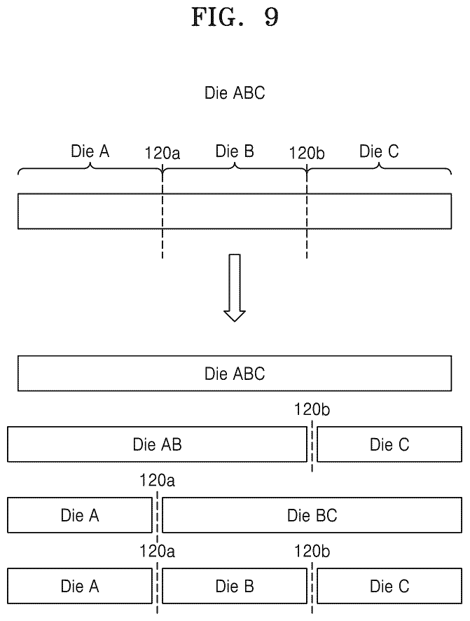

FIG. 9 is a conceptual view illustrating a case in which two optional dicing lines are formed on a die, according to example embodiments. Referring to FIG. 9, a die ABC may include a left optional dicing line 120a and a right optional dicing line 120b. Each of the optional dicing lines 120a and 120b may or may not be diced. When the optional dicing lines 120a and 120b are not diced, the die ABC may be manufactured without changes. When dicing is performed along the left optional dicing line 120a, a die A and a die BC may be formed. When dicing is performed along the right optional dicing line 120b, a die AB and a die C may be formed. When dicing is performed along both the left optional dicing line 120a and the right optional dicing line 120b, a die A, a die B, and a die C may be formed. When the die ABC is diced along the optional dicing lines 120a and 120b or is not diced, the die ABC, the die AB, the die BC, the die A, the die B, and the die C may be formed. In other words, a plurality of types of dies may be produced. For example, a total of 6 types of dies may be produced. Because the die ABC is a die produced with a single process, the die ABC having a large area may be generally a die having best performance. Because a die having a large area may have a reduced production yield as described above, the die ABC having best performance may be preferentially manufactured and then first KBDs in the die ABC may be diced. Accordingly, the die AB, the die BC, the die A, the die B, or the die C, each of which is a second KGD having a smaller area than the die ABC, may be produced. Because relatively-small area semiconductor chips having no defects may be produced from a large-area defective semiconductor chip through dicing, a production yield may be increased and/or production costs may be reduced.

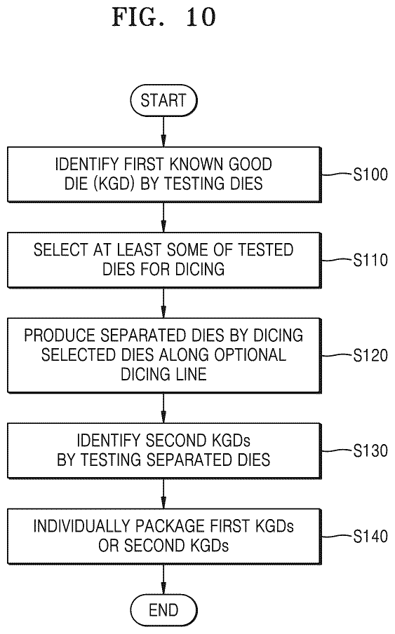

FIG. 10 is a flowchart of a method of manufacturing a semiconductor package including a semiconductor chip, according to example embodiments. A description of FIG. 10 that is the same as that given above will not be repeated herebelow.

Referring to FIG. 10, the method of manufacturing a semiconductor package including a semiconductor chip, according to example embodiments, includes operation s100 of identifying a first KGD through the above-described test of dies.

The method of manufacturing a semiconductor package including a semiconductor chip, according to example embodiments, includes, after operation s100, operation s110 of selecting at least some of the tested dies for dicing. The selected dies may be first KGDs or first KBDs. In other words, dies may be selected regardless of whether they are first KGDs or first KBDs. As described above with reference to FIG. 7, even when the selected dies correspond to first KGDs, supply of diced dies is required, and thus additional dicing may be performed, and accordingly the first KGDs may be diced.

Next, operation s120 of producing separated dies by dicing the selected dies along the optional dicing line is included. As described above, after the selected dies are moved and positioned on a carrier wafer, dicing may be performed.

Next, operation s130 of identifying second KGDs by testing the separated dies is included. With the above test, the second KGDs and the second KBDs may be identified.

Next, operation s140 of individually packaging the first KGDs or the second KGDs may be included. First KGDs and second KGDs not diced among the first KGDs may be individually packaged. As described above with reference to FIG. 6, in the case of a die having one optional dicing line, a total of three types of dies may be produced and packaged to produce three types of semiconductor packages. As described above with reference to FIG. 9, in the case of a die having two optional dicing lines, a total of six types of dies may be produced and packaged to produce six types of semiconductor packages. In other words, a plurality of types of semiconductor packages may be produced.

One of the above-described operations may further include a process in which an isolation block processing an electrical signal for a wire exposed on the cross-sections of the separated dies obtained by dicing along the optional dicing line is activated.

Although example embodiments have been disclosed for illustrative purposes, one of ordinary skill in the art will appreciate that diverse variations and modifications are possible, without departing from the spirit and scope of the inventive concepts. Thus, the above-described example embodiments should be considered in descriptive sense only and not for purposes of limitation.

While the inventive concepts have been particularly shown and described with reference to example embodiments thereof, it will be understood that various changes in form and details may be made therein without departing from the spirit and scope of the following claims.

What is claimed is:

1. A semiconductor chip comprising:
a front end of line (FEOL) including an active layer;
a back end of line (BEOL) including a plurality of metal layers including a wire;
an optional dicing line along which dicing is optionally performed;
an isolation block configured to process a signal for a discontinuous wire when the wire is discontinuous by being diced along the optional dicing line; and
a chip die on which the active layer is not formed around a cross section cut by the optional dicing line.

2. The semiconductor chip of claim 1, wherein the chip die comprises one or more of a CPU core, a GPU core, an NPU core, and a memory block.

3. The semiconductor chip of claim 1, wherein a number of the plurality of metal layers located around a cross-section of the optional dicing line is equal to or less than a number of the plurality of metal layers in a place other than a region around the cross-section of the optional dicing line.

4. The semiconductor chip of claim 3, wherein a signal layer, which is one layer among the plurality of metal layers around the cross-section of the optional dicing line, is composed of a wire.

5. The semiconductor chip of claim 1, wherein at least a portion of the wire is exposed on the cross-section of the optional dicing line.

6. The semiconductor chip of claim 5, further comprising a molding member configured to surround the chip die,
wherein the wire exposed on the cross-section of the optional dicing line is in direct contact with the molding member.

7. The semiconductor chip of claim 1, wherein each semiconductor chip obtained by dicing along the optional dicing line is configured to function as a single chipset, and each semiconductor chip not diced along the optional dicing line is configured to function as a single chipset.

8. The semiconductor chip of claim 1, wherein
the chip die has two optional dicing lines, and
at least one of the dicing lines is diced to form a plurality of types of chip dies, or the dicing lines are not diced to form a single type of chip die.

9. A semiconductor chip comprising:
an active layer;
a semiconductor wiring layer including a wire;
an optional dicing line along which dicing is optionally performed;
an isolation block configured to process a signal for a discontinuous wire when the wire is discontinuous by being diced along the optional dicing line; and
a chip die on which the active layer is not formed around a cross section cut by the optional dicing line.

10. The semiconductor chip of claim 9, wherein the isolation block includes a one time programmable (OTP) memory that activates the isolation block, when the chip die is diced along the optional dicing line.

11. The semiconductor chip of claim 9, wherein a number of the semiconductor wiring layers around the cross-section of the optional dicing line is equal to or less than a number of the semiconductor wiring layers located in a place other than a region around the cross-section of the optional dicing line.

12. The semiconductor chip of claim 9, wherein the isolation block is activated through an external pin or an external memory.

13. The semiconductor chip of claim 9, wherein the isolation block is configured to perform a function of preventing an electric signal for the discontinuous wire from floating, shorting, and leaking.

14. A method of producing a semiconductor package, the method comprising:
identifying first known good dies (KGDs) by testing dies including an optional dicing line along which dicing is optionally performed;
selecting at least some of the tested dies for dicing;
producing separated dies by dicing the selected dies along the optional dicing line;
identifying second KGDs by testing the separated dies; and
packaging each of at least some of the first KGDs or the second KGDs.

15. The method of claim 14, wherein, in the producing of the separated dies, an isolation block processing a signal for a wire exposed on cross-sections of the separated dies obtained by dicing along the optional dicing line is activated.

16. The method of claim 14, wherein the selecting for the dicing comprises selecting only a first known bad die (KBD) that does not correspond to a first KGD.

17. The method of claim 14, wherein the selecting for the dicing comprises selecting dies regardless of whether the dies are first KGDs.

18. The method of claim 14, wherein the producing of the separated dies by dicing comprises placing the selected dies on a carrier wafer and dicing the selected dies along the optional dicing line.

19. The method of claim 14, wherein
in the identifying of the first KGD, the optional dicing line included in each of the dies is provided as one,
the producing of the separated dies comprises dicing the one optional dicing line included in each of the selected dies, and
the packaging comprises individually packaging the first KGD and two types of second KGDs.

20. The method of claim 14, wherein
in the identifying of the first KGD, the optional dicing line included in each of the dies is provided as two,
the producing of the separated dies comprises dicing at least one of the optional dicing lines included in each of the selected dies, and
the packaging comprises individually packaging the first KGD and two types of second KGDs.
